(19) United States
(12) Patent Application Publication
(10) Pub. No.: US 2026/0322376 A1
(43) Pub. Date: Oct. 15, 2026

(54) DRIVER CIRCUIT FOR A BIDIRECTIONAL SWITCH WITH HIDDEN COMMON SOURCE AND METHOD FOR DRIVING SUCH A SWITCH

(71) Applicant: Infineon Technologies Austria AG, Villach (AT)

(72) Inventors: Saumitra SINGH, Bengaluru (IN); Shubhendu SITOKE, Bhopal (IN); Thomas BEER, Mauerstetten (DE); Nihit BAJAJ, San Diego, CA (US)

(21) Appl. No.: 19/629,226

(22) Filed: Mar. 26, 2026

(30) Foreign Application Priority Data
Apr. 11, 2025 (DE) 102025114411.7

(51) Int. Cl. H03K 17/687

(52) U.S. Cl. CPC H03K 17/6871

(57) ABSTRACT

Embodiments include a driver circuit for a bidirectional switch, wherein the bidirectional switch includes a gate terminal, a first and second drain terminal and a hidden, e.g., buried, common source (e.g., so that no terminal for measuring a voltage of the common source is available, e.g., a source which is not exposed). The driver circuit is configured to use or select a lower of a drain voltage of the first drain terminal and of a drain voltage of the second drain terminal in order to provide a drive signal to the gate terminal of the bidirectional switch.

### CROSS-REFERENCE TO RELATED APPLICATION

This application claims priority to Germany Patent Application No. 102025114411.7, filed Apr. 11, 2026, the contents of which are incorporated herein by reference in their entireties.

### TECHNICAL FIELD

Embodiments comprise a driver circuit for a bidirectional switch with a hidden common source and a method for driving such a switch.

Embodiments comprise methods to drive GaN (gallium nitride) bidirectional common source switches, for example, in protection fuse applications.

Embodiments are related to power and sensor systems, e.g., GaN power and sensor systems, e.g., PSS GaN.

Embodiments comprise GaN bidirectional switch driver eFuses (electronic fuses, e.g., for providing overcurrent protection for electronic circuits) and drivers for GaN bidirectional switches.

Embodiments are related to eFuses, or in general devices and methods for eFuse applications, and to overvoltage protection switches.

Embodiments comprise USB protection switches and methods and devices for battery management.

### BACKGROUND

GaN bidirectional common source switches (BDS) are a new class of products (e.g., as introduced by BL GaN—it is to be noted that embodiments also address, inter alia, functionally similar products). A main advantage of such switches is, for example, a significantly lower Rds-on*A for a back-to-back switch compared to a discrete implementation.

However, as the source of such a BDS switch is not exposed, traditional drive methodologies and circuits do not work or at least face severe drawbacks.

Therefore, it is desired to get a concept for driving a bidirectional switch with a hidden common source, which makes a better compromise between a complexity, efficiency and robustness of the switch driving.

This is achieved by the subject matters of the independent claims of the present application.

Further embodiments are defined by the subject matter of the dependent claims of the present application.

### SUMMARY

Embodiments comprise a driver circuit for a bidirectional switch, wherein the bidirectional switch comprises a gate terminal, a first and second drain terminal and a hidden, e.g., buried, common source (e.g., so that no terminal for measuring (e.g., directly) a voltage of the common source is available, e.g., a source which is not exposed). The driver circuit is configured to use (or for example to select) a lower of a drain voltage of the first drain terminal and of a drain voltage of the second drain terminal, in order to provide a drive signal to the gate terminal of the bidirectional switch (e.g., on the basis of the lower of the drain voltage of the first drain terminal and of the drain voltage of the second drain terminal).

For a better understanding of embodiments, first, an example for constraints for driving a bidirectional switch is discussed: It was recognized that for a bidirectional switch with a hidden, e.g., buried, common source, for example for a GaN bidirectional common source switch, due to the physical construction of the switch, for example, the following constraints may be placed on Vgd1 and Vgd2:
(1) Vdg1<BVMAX,
(2) Vdg2<BVMAX
(3) |Vd1−Vd2|(4) Vgd1<VGMAX
(5) Vgd2<VGMAX.

(with d: drain, g: gate, max: maximum, BVMAX: maximum breakdown voltage)

It was recognized that this may imply that the gate voltage cannot be higher than any of the drain voltages by more than VGMAX (e.g., 5.5V). As initially discussed, this creates a challenge on driving the switch, e.g., at least for conventional or traditional approaches: Specially, during turn on events, possible overvoltage transients could be created. For example, if one of the drains is 40V, and other drain is at 0V, and VGMAX=5V, if the switch is turned on with 45 V (Vdrain1+VGMAX), Vgd2 would exceed the VGMAX limit TILL the 2nd drain capacitor is charged by the BDS. Moreover, to limit inrush current, the charge times may be as high as few ms to seconds, sufficient to cause permanent damage to the switch.

Hence, it was recognized that by providing the drive signal to the gate terminal on the basis of (based on) the lower of the drain voltages of the first and second drain terminal, an efficient and robust switching may be achieved, whilst allowing to fulfill design-related constraints of such switches with hidden sources (e.g., common source switches).

Regarding the use or selection of the lower of the drain voltages, it is to be noted that embodiments are not limited to a distinct switching between the exact value of the one or the other drain voltage to provide the drive signal. According to some embodiments, both drain voltages may be used as inputs for the drive circuit, wherein the selection of the lower of the two voltages may be implemented as a charging of an output terminal or a discharging of the output terminal to an offset, or scaled, or scaled and offset, or offset and scaled, value of the lower of the two drain voltages.

Hence, a main aspect according to at least some embodiments may be considered as the provision of the drive signal based on the value (e.g., the voltage) of the lower of the two drain voltages.

Hence, the drive strategy according to embodiments may be based on identifying the lower of the two drain voltages and to determine the drive signal using or on the basis of said lower drain voltage (e.g., offset by an overdrive voltage to ensure reliable switching of the BDS).

### BRIEF DESCRIPTION OF THE DRAWINGS

The drawings are not necessarily to scale, emphasis instead generally being placed upon illustrating the principles of embodiments. In the following description, various embodiments are described with reference to the following drawings, in which:

FIG. 1 shows a schematic view of a driver circuit for a bidirectional switch, according to embodiments;

FIG. 2 shows a schematic view of a simulation model of a driver circuit for a bidirectional switch according to embodiments;

FIG. 3 shows a schematic view of a detailed version of an example of the simulation model of the driver circuit of FIG. 2;

FIG. 4 shows a schematic view of a simulation model of a voltage source circuit with optional features according to embodiments;

FIG. 5 shows a schematic plot of a simulation result of a driving scheme according to embodiments;

FIG. 6 shows a schematic view of a simulation model of a voltage sink circuit according to embodiments;

FIG. 7 shows a schematic view of a simulation model of a driver circuit for a bidirectional switch with additional, optional features, according to embodiments;

FIG. 8 shows a schematic view of a simulation model of another voltage sink circuit according to embodiments;

FIG. 9 shows a schematic view of a simulation model of a charge pump according to embodiments; and

FIG. 10 shows a schematic view of a simulation model of a driver stage according to embodiments.

### DETAILED DESCRIPTION

Equal or equivalent elements or elements with equal or equivalent functionality are denoted in the following description by equal or equivalent reference numerals even if occurring in different figures.

In the following description, a plurality of details is set forth to provide a more throughout explanation of embodiments. However, it will be apparent to those skilled in the art that embodiments may be practiced without these specific details. In other instances, well-known structures and devices are shown in block diagram form rather than in detail in order to avoid obscuring embodiments. In addition, features of the different embodiments described herein after may be combined with each other, unless specifically noted otherwise.

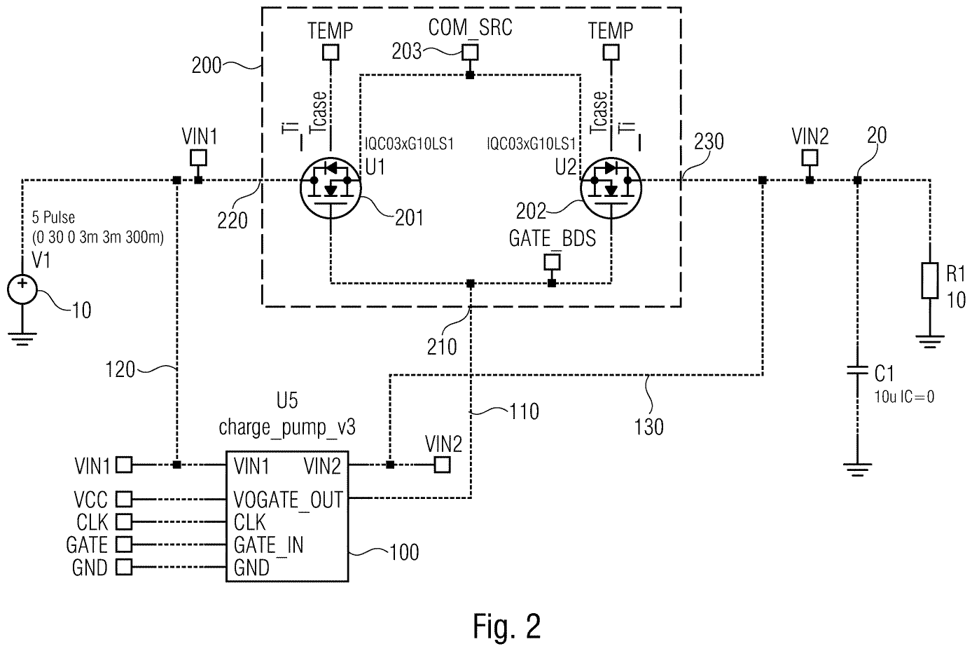

Furthermore, some figures (e.g., FIGS. 2 to 4 and FIGS. 6 to 10) show schematic views of simulation models. It is to be noted that these figures show respective interactions between the optional modules or entities of a driver circuit according to embodiments with each other as well as with a respective switch. Nevertheless, it is to be kept in mind that the structures are shown in the form of simulation models. Hence, inputs, outputs and the specific configurations are to be understood as examples, in particular as examples for testing and simulating embodiments. Nevertheless, the structure of the simulation model may correspond to the respective structure of the physical circuit, however the physical structure of such a simulation model is not limited to exact arrangement depicted by the simulation model.

Furthermore, it is understood that when an element is referred to as being “connected” or “coupled” to another element, it may be directly connected or coupled to the other element, or intermediate elements may be present. Other terms used to describe the relationship between elements should be construed in a similar fashion (e.g., “between” versus “directly between”, “adjacent” versus “directly adjacent”, and “on” versus “directly on”, etc.).

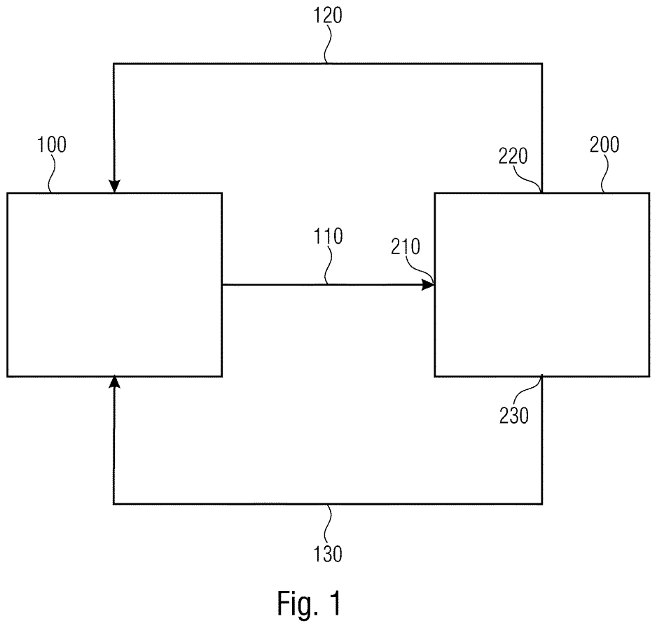

FIG. 1 shows a schematic view of a driver circuit for a bidirectional switch according to embodiments. FIG. 1 shows driver circuit 100 and bidirectional switch 200. The bidirectional switch 200 comprises a gate terminal 210, a first drain terminal 220 and a second drain terminal 230 and a hidden, e.g., buried, common source (e.g., so that no terminal for measuring a voltage of the common source is available, e.g., a source which is not exposed). The driver circuit 100 is configured to use or select a lower of a drain voltage 120 of the first drain terminal 220 and of a drain voltage 130 of the second drain terminal 230 and to provide a drive signal 110 to the gate terminal 210 on the basis of the lower of the drain voltages of the first and second drain terminal.

Regarding the functionality of the driver circuit of FIG. 1, reference is made to an example, according to which the switch 200 is a GaN switch. However, the following applies to other architectures of bidirectional common source switches in a corresponding manner.

As the common source terminal is not available (e.g., hidden) to system designer, due to construction of the GaN BDS switch, e.g., 200, a new driver circuit, e.g., 100 may be required to drive the GaN BDS switch (e.g., compared to conventional approaches).

A proposed drive strategy for BDS according to embodiments is, for example, as follows:
TURN ON: Apply minimum of the two drain voltages, e.g., of 220 and 230, + optionally overdrive voltage
TURN OFF: Apply ground

It is assumed (for example, according to embodiments it can be assumed) that neither of the two drain voltages would exceed the BDS switch's VDG or VD1−VD2 rating. Thus, it is assumed (for example, according to embodiments it can be assumed) that the system does not require (galvanic) isolation.

Regarding embodiments for floating switches, or in other words if, for example, floating BDS switches are required by the system, the drive strategy can optionally be modified to the following:
TURN ON: Apply minimum of the two drain voltages, e.g., of 220 and 230, + optionally overdrive voltage
TURN OFF: Apply minimum of the two drain voltages

Hence, optionally, the driver circuit 100 may be configured to provide the drive signal 110 to the gate terminal 210 using (e.g., as the combination of, e.g., as a sum of, e.g., on the basis of the sum of) the lower of the drain voltages of the first and second drain terminals and an overdrive voltage (e.g., a recommended gate voltage, e.g., Voverdrive, e.g., a voltage which is above a threshold voltage (e.g., Vth), e.g., Voverdrive=VGS−Vth, e.g., a voltage which “fully turns on” the transistor) to turn on the bidirectional switch.

As another optional feature, e.g., as discussed-above, optionally, in a referenced operating mode (e.g., a ground referenced operating mode, e.g., an operating mode wherein the driver circuit is referenced to ground or a fixed voltage), the driver circuit 100 may be configured to provide the drive signal 110 to the gate terminal 210 using (e.g., as the combination of, e.g., as the sum of, e.g., on the basis of the sum of) the lower of the drain voltages of the first and second drain terminals and the overdrive voltage to turn on the bidirectional switch 200 and to provide a ground signal or a fixed voltage signal as the drive signal to the gate terminal, in order to turn off the bidirectional switch 200.

Furthermore, optionally, in a floating operating mode (e.g., when not referenced to ground or to a fixed voltage), the driver circuit 100 may be configured to provide the drive signal 110 to the gate terminal 210 using (e.g., as the combination of, e.g., as the sum of, e.g., on the basis of the sum of) the lower of the drain voltages of the first and second drain terminals and the overdrive voltage to turn on the bidirectional switch 200 and to provide the drive signal 110 to the gate terminal 210 using (or for example as) the lower of the drain voltages of the first and second drain terminal to turn off the bidirectional switch.

Optionally, the overdrive voltage may be set according to the respective datasheet of the switch 200. For example, any transistor, e.g., Silicon mosfet or GaN, has a recommended gate voltage in datasheet, which “fully turns on” the transistor”, e.g., typically a few volts above threshold voltage. This may, for example, primarily be a function of technology implementation of the transistor structure (e.g., gate oxide thickness). For GaN with schottky gates, this voltage is, for example, about 4.5V to 5.5V for most of the GaN device vendors.

Next, reference is made to FIG. 2. FIG. 2 shows a schematic view of a simulation model of a driver circuit for a bidirectional switch according to embodiments.

FIG. 2 shows a simulation model of the driver circuit 100 and of the switch 200. As an example (e.g., for simulation purposes), the switch 200 is modeled as two separate transistors 201 and 202, which are coupled via their respective source, as indicated by the common source (COMSRC) 203. The gate terminal 210 of the model of the switch 200 is indicated as GATEBDS. The first and second drain voltages are indicated as VIN1, 120, and VIN2, 130.

Furthermore, e.g., for simulation purposes, a voltage source 10 is provided at the first drain terminal 220, and a combination 20 of a resistor and a capacitor at the second drain terminal 230.

In particular, FIG. 2 shows an example of the connection of the bidirectional switch, e.g., 200, and the driver, e.g., 100. For example, as shown in the models of FIG. 2, the driver circuit 100, e.g., also referred to as Charge pump+Driver block (chargepumpv3) (as it may comprise, optionally a charge pump and/or a drive stage (e.g., drive block)), may implement the drive for the BDS, 200. As an example, it may take as input the following
VIN1: First Drain Voltage, 120,
VIN2: Second drain voltage, 130,
VCC: VCC is a supply voltage, it should, for example, be regulated to a turn on voltage of the driver (e.g., VGS-max−margin)+2*Vd (where Vd=diode drop). This voltage can, for example, be generated via an LDO (e.g., Low Dropout Regulator)
CLK: A clock for charge pump. The clock frequency can or would, for example, depend on charge pump capacitors
GATE: Gate Control Signal

Here, it is to be noted that a driver circuit according to embodiments may optionally be configured to adapt the voltage regulation (e.g., for providing VCC) to a respective “diode drop” voltage (as will be discussed in the following). Hence, as an optional feature, the driver circuit or respectively a charge pump thereof may comprise a voltage regulator for providing VCC. Optionally, the driver circuit according to embodiments may be configured to adjust to different “diode drop” voltages in the regulation.

According to embodiments, diode voltage variation with process, temperature is possible. For example, a designer may design or should design for the worst case. For example, if a diode drop voltage is expected to be typically 0.7 V but 1 V in the worst case, the designer could, for example, design for 0.7 V. Assume VGS-max=6V, margin=0.5V, then an LDO voltage may be regulated to (6−0.5)+20.7 V=6.9 V. If the diode drop voltage changes to 1 V, then the effective voltage available to the gate would be 6.9−21 V=4.9 V, which is still sufficient to turn on the switch (recommended is, for example, 4V or higher).

Furthermore, according to embodiments, the margin (e.g., Vmargin) may, for example, typically, be set as 10% of the rated maximum gate-source voltage in the datasheet, e.g., to accommodate transient spikes on voltage. For example, if the datasheet indicates that the maximum is 6 V, designers, for example typically, design for a 5.5 V DC, to allow for 0.5 V spikes or transients. The primary maximum Vgs voltage is specified, for example, as absolute maximum in datasheet for a given switch, e.g., for a given discrete GaN (or MOSFET).

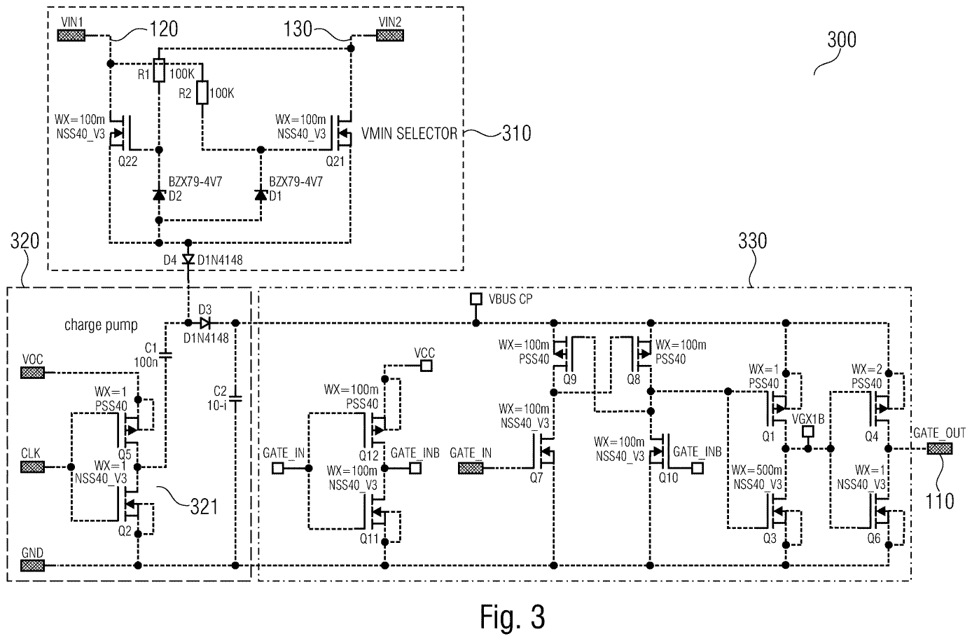

Next, reference is made to FIG. 3. FIG. 3 shows a schematic view of an example of a detailed version of the simulation model of the driver circuit of FIG. 2. In FIG. 3 an example for an implementation of charge pump+driver (e.g., chargepumpv3, e.g., comprising charge pump 320 and driver stage 330) is shown.

The driver circuit (e.g., also referred to as charge pump) optionally comprises or even contains 3 blocks: minimum voltage selector (e.g., also referred to as voltage source circuit), charge pump, and driver+level shifter (e.g., also referred to as drive stage).

For the charge pump and driver+level shifter blocks standard implementations available in prior art may be used. Clock and VCC can, for example, be generated from VIN1, VIN2.

Hence, in detail, FIG. 3 shows a schematic view of a model of a driver circuit 300 according to embodiments, comprising a voltage source circuit 310, a charge pump 320 and a drive stage 330 (e.g., a level shifter). Regarding FIGS. 1 and 2, driver circuit 300 may correspond to element 100.

The voltage source circuit 310, e.g., also referred to as minimum voltage selector or Vmin selector, is configured to obtain or provide a voltage source signal, e.g., VMIN_SRC, using, or on the basis of (e.g., by selecting), the lower of the drain voltage of the first drain terminal and of the drain voltage of the second drain terminal, in order to provide the drive signal using, or on the basis of, the voltage source signal to turn on the bidirectional switch. For example, the voltage source circuit 310 may be configured to provide the lower of the of the drain voltage of the first drain terminal and of the drain voltage of the second drain terminal as the voltage source signal, to obtain the drive signal.

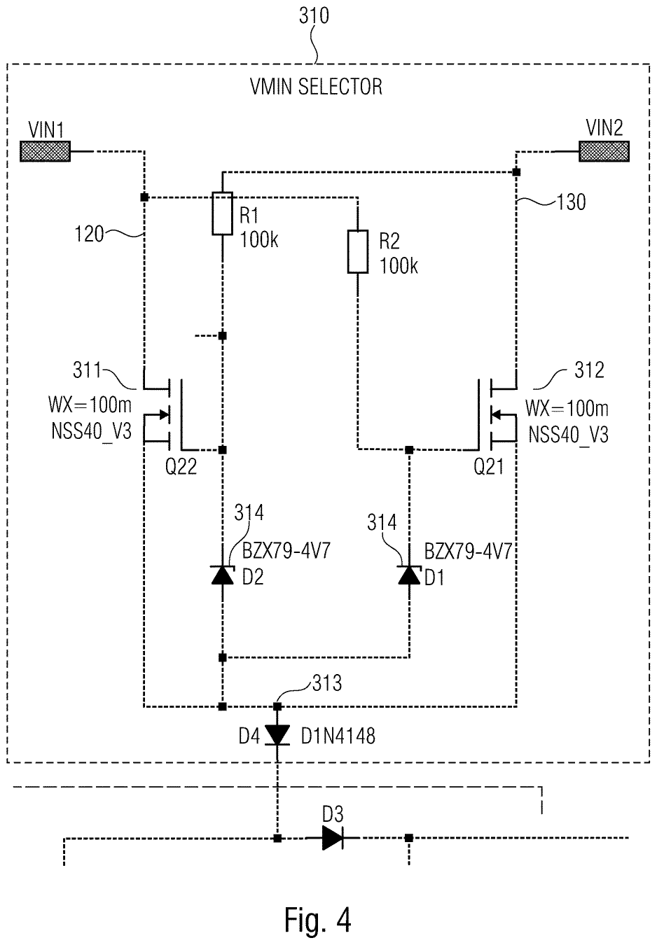

The specific implementation shown in FIG. 3 is to be understood as an example, in order to achieve said functionality. Circuit 310 will be discussed in detail, with its optional features, in the context of FIG. 4.

FIG. 4 shows a schematic view of a simulation model of the voltage source circuit 310 with optional features according to embodiments. Hence, FIG. 4 shows an example for an implementation of a minimum voltage selector according to embodiments.

As shown in FIG. 4, as optional features, the voltage source circuit 310 comprises cross-coupled transistors 311 and 312 (also referred to as Q22 and Q21). Furthermore, as discussed above, the voltage source circuit is configured to provide a voltage source signal, e.g., VMIN_SRC, using, or on the basis of, the lower of the drain voltage 120 of the first drain terminal and of the drain voltage 130 of the second drain terminal, in order to provide the drive signal 110 to turn on the bidirectional switch.

As shown in FIG. 4 the voltage source circuit 310 may optionally comprise cross-coupled NMOS transistors.

Furthermore, as an example, the drain terminal of the first transistor 311 of the cross-coupled transistors may be configured to be provided with the drain voltage 120 of the first drain terminal of the bidirectional switch and the gate terminal of the first transistor 311 may be configured to be provided with the drain voltage 130 of the second drain terminal of the bidirectional switch. The drain terminal of the second transistor 312 of the cross-coupled transistors may be configured to be provided with the drain voltage 130 of the second drain terminal of the bidirectional switch and the gate terminal of the second transistor 312 may be configured to be provided with the drain voltage 120 of the first drain terminal of the bidirectional switch.

In addition, the voltage source circuit 310 comprises an output terminal 313 to provide the voltage source signal using, or on the basis of, the lower of the drain voltages of the first and second drain terminal. The output terminal 313 of the voltage source circuit 310 is coupled with the source terminals of the cross-coupled transistors.

As another optional feature, the voltage source circuit 310 comprises voltage protection elements 314 at the gates of the cross-coupled transistors, as an optional feature coupled between the gates and the output terminal 313.

Optionally, diode D4 may as well be part of the voltage source circuit, so that the output terminal 313 may considered at the output of D4 and not at the input, as shown, so that the voltage source signal may be affected by the diode drop voltage of D4.

The voltage protection elements 314 comprise, as an example, Zener diodes. However, optionally, the voltage protection elements 314 may, alternatively or in addition comprise NMOS transistors in diode configuration, in a stack configuration or in a cascode configuration.

The cross-coupled NMOS transistor 311, 312 may work as follows: The transistor source would be equal to the transistor drain, if the transistor gate is higher than the transistor source by Vth.

With VMIN available, a rail voltage of VMIN+VCC(−2*Vdiode) can be generated using a charge pump circuit, e.g., 320. This rail can then be used to turn on the BDS switch e.g., 200, with the driver.

As discussed above, a protection 314 in the form of a Zener protection is provided at the gates of Q21 and Q22. This may, for example, ensure that Q21, Q22 do not suffer Vgs stresses. Again, it should be noted that, for example in a monolithic implementation, the Zener protection could be realized according to embodiments with NMOS in diode configuration (drain and gate shorted), or a stack/cascode implementation.

Hence, according to embodiments: To drive the bidirectional switch, a drive strategy based on the minimum of the two drain voltages+a Vgs turn-on voltage (e.g., an overdrive voltage) may be chosen. For example, as shown in FIG. 4, embodiments may comprise a circuit implementation which involves cross-coupled NMOS transistors.

Returning to FIG. 3, reference is made to the examples for the charge pump 320 and the level shifter 330 (e.g., also referred to as drive stage).

As shown, the charge pump 320 may, as an example, comprise an inverter stage 321, which may be controlled by the clock signal CLK. Hence, capacitor C1 may be charged to VCC+VMIN−Vdiode(D4), with VMIN being, for example, the lower of VIN1 and VIN2 (or optionally a scaled or offset or scaled and offset version thereof). Considering a second diode voltage drop of D3, the rail voltage at VBUS_CP may be obtained as VMIN+VCC(−2*Vdiode), wherein, for example Vdiode(D4)=Vdiode(D3)=Vdiode).

Accordingly, VCC may be regulated to VGS-Max+2*Vdiode, to compensate for the two diode drops due to D3 and D4 in FIG. 3 and to provide a sufficient overdrive.

Hence, a driver circuit according to embodiments may optionally comprise a charge pump, wherein the voltage source circuit is configured to provide the voltage source signal, e.g., VMIN, e.g., VMIN_SCR, or a scaled and/or offset version thereof (e.g., offset by diode drops), to the charge pump and wherein the charge pump is configured to offset the voltage source signal, in order to provide the drive signal to the gate terminal of the bidirectional switch, e.g., as a pull-up signal, to turn on the bidirectional switch.

Hence, in other words, optionally, the charge pump may be configured to offset the voltage source signal by the overdrive voltage. As another optional feature, the charge pump may, for example, be configured to offset the voltage source signal, in order to compensate internal diode voltage drops of the driver circuit.

Level shifter 330 (e.g., also referred to as drive stage) may provide the drive signal GATEOUT based on the voltage source signal, or more specifically, here based on the rail voltage VBUSCP obtained from said voltage source signal.

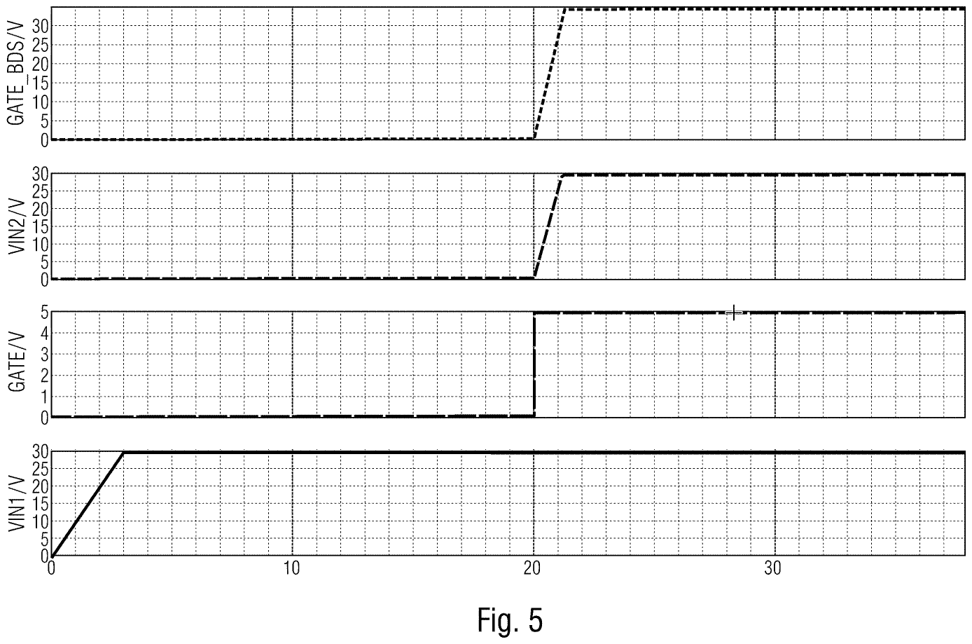

Next, reference is made to FIG. 5, showing a schematic plot of a simulation result of a driving scheme according to embodiments. FIG. 5 shows examples for the drive signal for the gate terminal (GATE_BDS in Volts), the voltages at the first and second drain terminal (VIN1, VIN2 in Volts) and the gate control signal (GATE in Volts) over time in ms.

FIG. 5 hence shows an example of the driving scheme. Between 0 and 20 ms, the gate control signal is 0 V. In this case, the drive signal remains at 0 V. At 20 ms the gate control signal switches to 5 V, or in other words, the switch is turned on. As can be seen between 20 ms and 21 ms the drive signal is following the lower of the two drain voltages (e.g., offset by an overdrive voltage, e.g., offset by VGS-max−Vmargin).

Next, advantages of embodiments, inter alia over other diving schemes, are discussed.

Case 1: Use current drive schemes for silicon (e.g., turn on with “input voltage” 5 V in a protection switch, turn off with ground). Initially, the output voltage would be at 0 V. Due to softstart inrush limiting, for the duration of soft start time (ms to 100s of ms) a VDG>5 V is established, potentially destroying the switch.

Case 2: max(VIN1, VIN2)+5V: same issue

Hence, embodiments allow overcoming the above drawbacks. In particular, a safe and robust start procedure may be achieved.

Next, reference is made to a 3rd case, which embodiments may implement:

Case 3: turn on: min(VIN1, VIN2)+5V, turn-off: min(VIN1, VIN2)

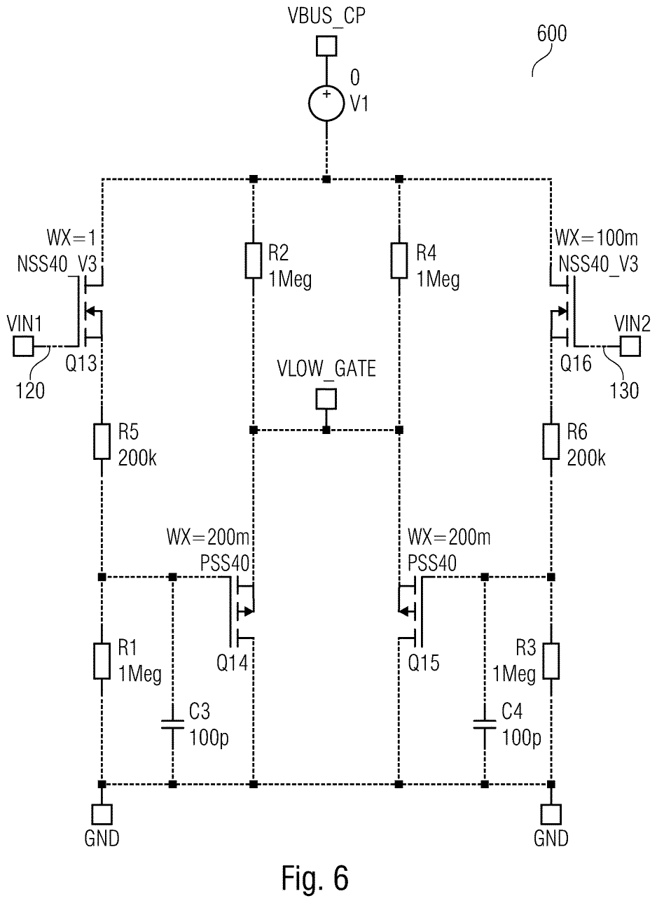

This is an attractive scheme in terms of (for example always) ensuring reliable operation of the switch. The generation of a sink capable of min(VIN1, VIN2) may be implemented using additional circuitry. Hence, embodiments may address or be relevant for galvanic isolated/floating BDS. A possible implementation of generating the negative rail is shown in FIG. 6.

FIG. 6 shows a schematic view of a simulation model of a voltage sink circuit according to embodiments. The voltage sink circuit 600 comprises a first and second discharge path to discharge a voltage sink signal VLOW_GATE (e.g., also referred to as VMIN_SINK) via the first discharge path using the drain voltage 120 of the first drain terminal, if the drain voltage 120 of the first drain terminal is lower than the drain voltage 130 of the second drain terminal, or via the second discharge path using the drain voltage 130 of the second drain terminal, if the drain voltage 230 of the second drain terminal is lower than the drain voltage 120 of the first drain terminal, in order to provide the drive signal to turn off the bidirectional switch.

For example, according to embodiments, the voltage sink circuit may be configured to discharge the voltage sink signal (e.g., also referred to as VMIN_SINK) to the drain voltage of the first drain terminal via the first discharge path, if the drain voltage of the first drain terminal is lower than the drain voltage of the second drain terminal, or to the drain voltage of the second drain terminal, via the second discharge path, if the drain voltage of the second drain terminal is lower than the drain voltage of the first drain terminal, in order to provide the lower (e.g., also referred to as VMIN_SRC) of the drain voltage of the first drain terminal and of the drain voltage of the second drain terminal as the voltage sink signal (e.g., also referred to as VMIN_SRC) in order to provide the drive signal to turn off the bidirectional switch.

Hence, as an example, the lower of the two drain voltages may be selected and the voltage sink signal may be discharged until it reaches said lower voltage or a scaled or offset or scaled and offset version thereof.

As shown in FIG. 6, as optional features, the first discharge path may comprise a first transistor, Q13, and second transistor, Q14, and the second discharge path may comprise a third transistor, Q16, and a fourth transistor, Q15. As shown, as an example, the first and third transistor may be of a first channel type, e.g., n-channel, and the second and fourth transistor may be of a second channel type, e.g., p-channel, which is different from the first channel type.

As further optional features, a gate terminal of the first transistor is configured to be provided with the drain voltage 120 of the first drain terminal of the bidirectional switch and a source terminal of the first transistor is coupled with a gate terminal of the second transistor, optionally via a voltage divider.

As further optional features, a gate terminal of the third transistor is configured to be provided with the drain voltage 130 of the second drain terminal of the bidirectional switch and a source terminal of the third transistor is coupled with a gate terminal of the fourth transistor, optionally via a voltage divider.

Furthermore, optionally, the drain terminals of the first and third transistor are configured to be provided with a common drain supply voltage and the drain terminals of the second and fourth transistor are configured to be coupled with a common reference voltage and the source terminals of the second and fourth transistor are coupled and configured to discharge the voltage sink signal, e.g., VLOW_GATE, using the lower of the of the drain voltages of the first drain terminal and of the drain voltage of the second drain terminal, e.g., so as to discharge the voltage sink signal to the lower of the of the drain voltages or a scaled or offset or scaled and offset version thereof.

Hence, FIG. 6 may show a schematic view of a model of a negative rail generation block.

Regarding FIG. 6, an example for the working principle of the circuit is discussed: When the bidirectional switch (e.g., GaN switch) is turned OFF, according to embodiments, its gate should, for example, be the lower of the two drain voltages. In a turn off situation, the gate may be pulled down, and hence a sink current may be needed to discharge the gate voltage.

The FIG. 6 circuit primarily provides two discharge paths: The one on the left (comprising Q13, Q14) may try to discharge to VIN1, while the one on the right (comprising Q15, Q16) may try to discharge to VIN2. When both discharge paths are active, the gate is discharged to the lower of the two voltages, thus achieving Vmin on the sink path.

Regarding the functionality of each leg (e.g., each discharge path): As an example, we will consider the left leg. Q13, R5 and R1 form a source follower circuit: In a source follower configuration the source node “follows” the gate node with a ~Vt shift. Thus, Q13's source, may, for example, be at (VIN1−Vthn). This voltage may be scaled by R1/(R1+R5)=K1 and may become the gate of Q14. Q14 is, as an example, a PMOS, thus it is also used in a source follower configuration. Therefore, Q14's source (VLOWGATE) would, for example, be at Vg(Q14)+Vthp. This is the same as Vthp+K1VIN1−KVthn. With some transistor sizing, it can, optionally, be ensured that K1*Vthn~=Vthp. Thus, VLOWGATE=K1*VIN1. For K1~=1, thus VLOW_GATE=VIN1.

A similar pulldown on the right side may try to pull VLOW_GATE to VIN2. As both are independent pulldowns, the lower pulldown voltage wins.

Bidirectional switches, BDS switches, may, for example, offer tremendous benefits in applications like eFuse, hot-swap controllers, overvoltage protection switches. These products, for example, when built around GaN BDS device, offer, for example, 50% area saving OR, for example, half the resistance for a same footprint, to the system designers (e.g., when compared to a Silicon vertical power FET).

However, as current drivers cannot address the limitations posed to drive a discrete GaN BDS (or in more general terms bidirectional switches with common, e.g., hidden sources), it could slow down the discrete FETs adoption. Hence, embodiments addressing such designs enable developing GaN based integrated eFuse, OVP (e.g., overvoltage protection function) and/or hot-swap controller products. Potential application areas of embodiments include, inter alia, USB-C protection switches and/or Battery management systems.

Embodiments (such as the proposed driver+switch system) can, for example, replace existing silicon based back-to-back switches. If the switch+driver is produced as an integrated product, it may be built as a pin-to-pin replacement of an existing silicon-based solution, for example, with enhanced features like 50% lower Rds-on.

Furthermore, it is to be noted that embodiments may also address or comprise, custom silicon implementations (e.g., having cross-coupled driver), which may, for example, have RE (e.g., emitter resistors) of IC.

### Advantages of Embodiments

Compared to the above-discussed embodiments, other drive strategies, like using an comparator based detection and switches to generate min(Vd1, Vd2) could be potentially used. Disadvantages of such scheme include comparator delays slowing the fast turn off of the switch. Hence, the above-discussed embodiments allow faster switching.

Furthermore, clamping of a traditional driver with external components like Zener is potentially possible, at the cost of extra BOM (e.g., bill of materials). Hence, driver circuits according to embodiments comprise less parts and hence have a lower complexity.

In general, embodiments allow integrating bidirectional common source switches, such as GaN BDS.

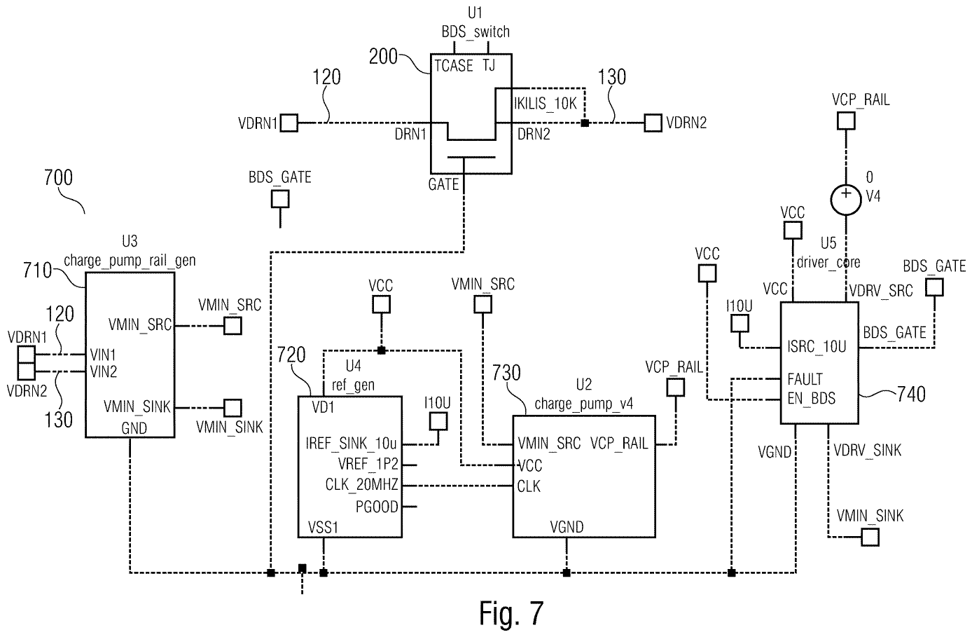

Next, reference is made to FIG. 7. FIG. 7 shows a schematic view of a model of a driver circuit for a bidirectional switch with additional, optional features, according to embodiments. FIG. 7 may hence show top level connections of a driver circuit according to embodiments.

FIG. 7 shows a simulation model for switch 200, with drain voltages 120 and 130. For simulation purposes, in the configuration shown, the gate terminal of the switch is connected to ground. For a respective application, the gate terminal may be coupled with the BDS_GATE terminal.

The driver circuit 700 comprises a voltage selector block 710. As an example, this block 710 comprises a voltage source circuit for providing a voltage source signal, VMINSRC, and a voltage sink circuit, in order to enable a discharging of the gate terminal to a voltage sink signal VMINSINK.

The driver circuit 700 further comprises support block 720, for providing the clock signal CLK. The support block 720 is supplied with a supply voltage VCC. Furthermore, the support block 720 comprises a current sink IREFSINK10u.

The driver circuit 700 further comprises a charge pump block 730, for providing a rail voltage VCPRAIL on the basis of the VMINSRC voltage. Therefore, the charge pump is provided with the supply voltage VCC and the clock signal CLK.

Furthermore, the driver circuit 700 comprises a driver block 740 (e.g., a drive stage) for providing the drive signal BDSGATE. The driver block 740 is provided with the supply voltage VCC, the VMINSINK and the rail voltage VCPRAIL. Furthermore, for providing a discharge path, the driver block 740 is coupled with the current sink IREFSINK_10u.

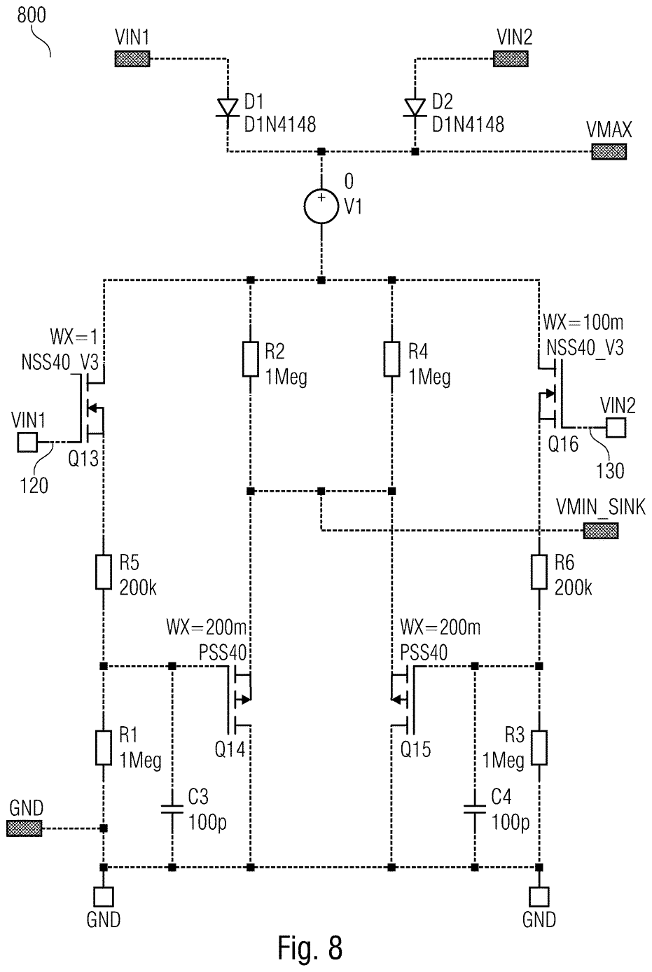

Examples for implementations of the respective blocks 710 to 740 are discussed with respect to FIG. 8 to 10.

FIG. 8 shows a schematic view of a simulation model of a voltage sink circuit according to embodiments.

Block 710 (e.g., chargepumprailgen) may, for example, include the circuit as shown in FIG. 8: This block may hence generate the VMINSRC (VMIN source) and/or VMINSINK (VMIN Sink rail). VMINSRC rail can, for example, be further used to add charge pump voltage. In other words, using the charge pump, the VMIN_SRC (e.g., the voltage source signal) may be offset, e.g., by an overdrive voltage and/or in order to offset internal voltage drops (e.g., diode voltage drops).

However, block 710 may, for example, comprise the circuitry 800 as shown in FIG. 8, in addition to a voltage source circuit, e.g., 400, as discussed in the context of FIG. 4. Hence, the VMIN_SRC may be provided as the voltage source signal, as discussed for FIG. 4.

For example, block 710 may comprise the circuit shown in FIG. 8, in order to discharge the BDS_GATE using the lower of the two drain voltages VIN1, VIN2. As shown in FIG. 8, a diode configuration (D1, D2) may be used in order to provide the maximum of VIN1 and VIN2, to enable a robust switching of Q13 and Q13 and of Q14 and Q15, e.g., to ensure sufficient drain source voltages.

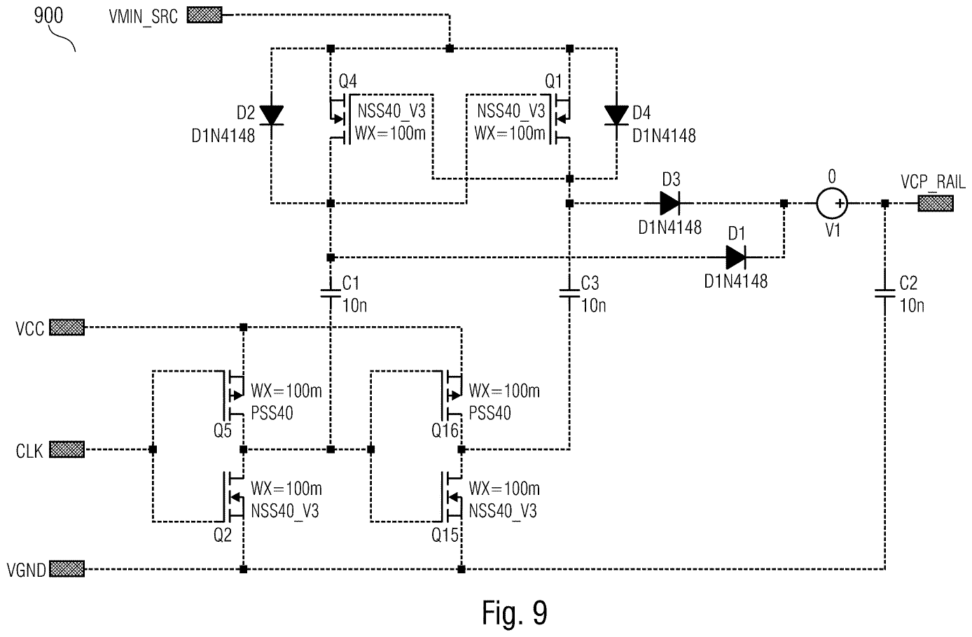

FIG. 9 shows a schematic view of a simulation model of a charge pump according to embodiments.

FIG. 9 may show the block 730 (e.g., chargepumpv4): This block may generate a charge pump voltage (VMIN_SRC+VCC−Vdiode). Hence, FIG. 9 may show an alternative to the charge pump as shown in FIG. 3, element 320.

Charge pump 900 is provided with a supply voltage VCC and the clock signal CLK. The pump 900 comprises two inverter stages (Q5+Q2 and Q16+Q15) for charging respective capacitors C1 and C3.

Using transistors Q1 and Q4, e.g., compared to the implementation 320 of FIG. 3, a second voltage drop because of diodes D2 and D4 (in addition to the voltage drops caused by D1 and D3 in FIG. 9), corresponding to diode D4 of FIG. 3, may be prevented by bypassing diodes D2 and D4 of FIG. 9.

Furthermore, optionally, the charge pump may be configured to offset the voltage source signal by the overdrive voltage and/or to offset the voltage source signal, in order to compensate internal diode voltage drops of the driver circuit. For example, the charge pump may comprise an additional VCC regulation in order to offset voltage source signal by Vdiode (or for example by 2*Vdiode, referring to FIG. 3) and/or by Voverdrive.

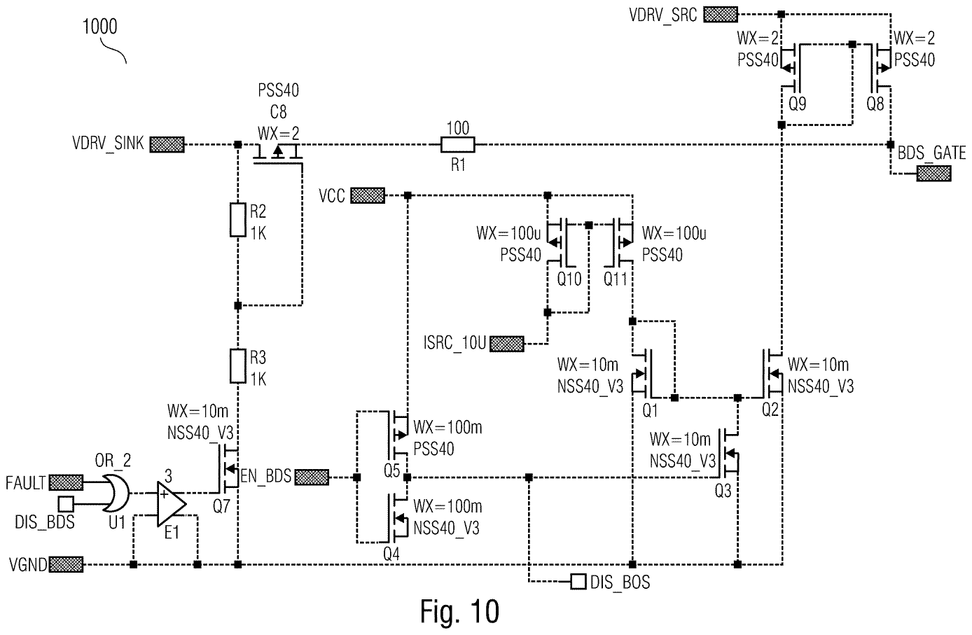

FIG. 10 shows a schematic view of a simulation model of a driver stage according to embodiments. Block 740 of FIG. 8 may be or may comprise the driver stage 1000.

Driver stage 1000 is provided with an enabling signal ENBDS, for enabling the bidirectional switch. Using inverter stage Q4, Q5 the inverted signal DISBDS is obtained. Using current mirrors Q10, Q11 and Q1, Q2 and Q8, Q9, the drive signal BDSGATE may be charged using the VDRVSRC signal. As discussed for FIG. 7, the VDRVSRC may correspond to the VMINSRC signal, e.g., the voltage source signal.

On the other hand, for discharging the gate of the switch, BDSGATE may be discharged via Q6, Q7 using VDRVSINK. As discussed for FIG. 7, the VDRVSRC may correspond to the VMINSINK signal.

Hence, regarding the driver core schematic of FIG. 10, stage 1000 may, for example, generate the gate voltage via a pullup path (Q8-Q9 current mirror) and a pulldown path (Q1-Q2 current mirror).

Further remarks:

Both common source and common drain architecture can attain bidirectional blocking. Common drain GaN with two gates is possible as a monolithic switch, but, for low voltages (e.g., <100V), a common source single gate topology is more area efficient than two gate common drain, while achieving the same performance. Area efficiency (for example about 30-40% lower area for the same Rds-on) is, for example, the primary reason for choosing common source.

Embodiments hence enable to exploit said advantages: A core aspect of embodiments may be considered “the application of Vmin selection for a bidirectional common source switch (BDS), wherein said common source is not available for the control, hence only the drain terminals of the switch”

Hence, embodiments address the general concept of driving said BDS switches based on the lower of the two drain voltages. In particular, embodiments provide for a low quiescent current method of obtaining this voltage without active comparators. Furthermore, implementations allow both to turn-on and to turn-off of a respective BDS switch once this voltage is derived.

In the following embodiments are summarized:
Embodiment 1: A driver circuit for a bidirectional switch, wherein the bidirectional switch comprises a gate terminal, a first and second drain terminal and a hidden, e.g., buried, common source (e.g., so that no terminal for measuring a voltage of the common source is available, e.g., a source which is not exposed), wherein the driver circuit is configured to use a lower of a drain voltage of the first drain terminal and of a drain voltage of the second drain terminal in order to provide a drive signal to the gate terminal of the bidirectional switch. For example, the driver circuit may be configured to select a lower of a drain voltage of the first drain terminal and of a drain voltage of the second drain terminal and the driver circuit may be configured to provide a drive signal to the gate terminal on the basis of the lower of the drain voltages.
Embodiment 2: The driver circuit according to embodiment 1, wherein the driver circuit is configured to provide the drive signal to the gate terminal using (e.g., as a combination of, e.g., as a sum of) the lower of the drain voltages of the first and second drain terminals and an overdrive voltage (e.g., a recommended gate voltage, e.g., Voverdrive, e.g., a voltage which is above a threshold voltage (e.g., Vth), e.g., Voverdrive=VGS−Vth, e.g., a voltage which “fully turns on” the transistor) to turn on the bidirectional switch. For example, the driver circuit may be configured to provide the drive signal to the gate terminal as a sum of the lower of the drain voltages and an overdrive voltage to turn on the switch.
Embodiment 3: The driver circuit according to embodiment 2, wherein, in a referenced operating mode, the driver circuit is configured to provide the drive signal to the gate terminal using the lower of the drain voltages of the first and second drain terminals and the overdrive voltage (e.g., a recommended gate voltage, e.g., Voverdrive, e.g., a voltage which is above a threshold voltage (e.g., Vth), e.g., Voverdrive=VGS−Vth, e.g., a voltage which “fully turns on” the transistor) to turn on the bidirectional switch; and to provide a ground signal or a fixed voltage signal as the drive signal to the gate terminal, in order to turn off the bidirectional switch. For example, the driver circuit may be configured to provide the drive signal as the sum of the lower of the drain voltages and the overdrive voltage to turn on the switch.
Embodiment 4: The driver circuit according to any of embodiments 2 to 3, wherein, in a floating operating mode, the driver circuit is configured to provide the drive signal to the gate terminal using the lower of the drain voltages of the first and second drain terminals and the overdrive voltage (e.g., a recommended gate voltage, e.g., Voverdrive, e.g., a voltage which is above a threshold voltage (e.g., Vth), e.g., Voverdrive=VGS−Vth, e.g., a voltage which “fully turns on” the transistor) to turn on the bidirectional switch; and to provide the drive signal to the gate terminal using (or for example as) the lower of the drain voltages of the first and second drain terminal to turn off the bidirectional switch. For example, the driver circuit may be configured to provide the drive signal as the sum of the lower of the drain voltages and the overdrive voltage. For example, the driver circuit may be configured to provide the drive signal as the sum of the lower of the drain voltages and the overdrive voltage to turn on the switch and to provide the drive signal as the lower of the drain voltages to turn off the switch.
Embodiment 5: The driver circuit according to any of embodiments 1 to 4, wherein the driver circuit comprises a voltage source circuit, e.g., a minimum voltage selector, comprising cross-coupled transistors (e.g., so that the transistors are connected in parallel, wherein an output of one transistor is coupled to an input of the other transistor and vice versa) and wherein the voltage source circuit is configured to provide a voltage source signal, e.g., VMIN_SRC, using the lower, e.g., VMIN_SRC, of the drain voltage of the first drain terminal and of the drain voltage of the second drain terminal; in order to provide the drive signal on the basis of the voltage source signal to turn on the bidirectional switch. For example, the driver circuit may be configured to provide the lower of the drain voltage of the first drain terminal and of the drain voltage of the second drain terminal as the voltage source signal, in order to provide the drive signal as an offset version (or scaled version or scaled and offset version) of the voltage source signal.
Embodiment 6: The driver circuit according to embodiment 6, wherein the voltage source circuit comprises cross-coupled NMOS transistors.
Embodiment 7: The driver circuit according to any of embodiments 5 to 6, wherein a drain terminal of a first transistor of the cross-coupled transistors is configured to be provided with the drain voltage of the first drain terminal of the bidirectional switch and wherein a gate terminal of the first transistor is configured to be provided with the drain voltage of the second drain terminal of the bidirectional switch; wherein a drain terminal of a second transistor of the cross-coupled transistors is configured to be provided with the drain voltage of the second drain terminal of the bidirectional switch and wherein a gate terminal of the second transistor is configured to be provided with the drain voltage of the first drain terminal of the bidirectional switch; and wherein the voltage source circuit comprises an output terminal to provide the voltage source signal using the lower, e.g., VMIN, of the drain voltages of the first and second drain terminal, and wherein the output terminal of the voltage source circuit is coupled with the source terminals of the cross-coupled transistors. For example, the voltage source circuit may be configured to provide the lower of the drain voltages of the first and second drain terminal as the voltage source signal.
Embodiment 8: The driver circuit according to embodiment 7, wherein the voltage source circuit comprises voltage protection elements at the gates of the cross-coupled transistors, e.g., coupled between the gates and the output terminal.
Embodiment 9: The driver circuit according to embodiment 8, wherein the voltage protection elements comprise Zener diodes and/or NMOS transistors in diode configuration, in a stack configuration or in a cascode configuration.
Embodiment 10: The driver circuit according to any of embodiments 5 to 9, wherein the driver circuit comprises a charge pump; wherein the voltage source circuit is configured to provide the voltage source signal, e.g., VMIN_SCR, to the charge pump; and wherein the charge pump is configured to offset the voltage source signal, in order to provide the drive signal to the gate terminal of the bidirectional switch, e.g., as a pull-up signal, to turn on the bidirectional switch.
Embodiment 11: The driver circuit according to embodiment 10, wherein the charge pump is configured to offset the voltage source signal by the overdrive voltage.
Embodiment 12: The driver circuit according to embodiment 10 or 11, wherein the charge pump is configured to offset the voltage source signal, in order to compensate internal diode voltage drops of the driver circuit.
Embodiment 13: The driver circuit according to any of the embodiments 1 to 12, wherein the driver circuit comprises a voltage sink circuit with a first and second discharge path; wherein the voltage sink circuit is configured to discharge a voltage sink signal, e.g., VMIN_SINK, via the first discharge path using the drain voltage of the first drain terminal, if the drain voltage of the first drain terminal is lower than the drain voltage of the second drain terminal, or via the second discharge path using the drain voltage of the second drain terminal, if the drain voltage of the second drain terminal is lower than the drain voltage of the first drain terminal, in order to provide the drive signal to turn off the bidirectional switch.

For example, the driver circuit may be configured to discharge the voltage sink signal to the drain voltage of the first drain terminal via the first discharge path if the drain voltage of the first drain terminal is lower than the drain voltage of the second drain terminal, or to the drtain voltage of the second drain terminal via the second discharge path if the drain voltage of the second drain terminal is lower than the drain voltage of the first drain terminal.
Embodiment 14: The driver circuit according to embodiment 13, wherein the first discharge path comprises a first transistor, e.g., Q13] and second transistor, e.g., Q14] and the second discharge path comprise a third transistor, e.g., Q16] and a fourth transistor, e.g., Q15, wherein the first and third transistor are of a first channel type, e.g., n-channel, and wherein the second and fourth transistor are of a second channel type, e.g., p-channel, which is different from the first channel type; wherein a gate terminal of the first transistor is configured to be provided with the drain voltage of the first drain terminal of the bidirectional switch and wherein a source terminal of the first transistor is coupled with a gate terminal of the second transistor, e.g., via a voltage divider, wherein a gate terminal of the third transistor is configured to be provided with the drain voltage of the second drain terminal of the bidirectional switch and wherein a source terminal of the third transistor is coupled with a gate terminal of the fourth transistor, e.g., via a voltage divider, wherein the drain terminals of the first and third transistor are configured to be provided with a common drain supply voltage; wherein the drain terminals of the second and fourth transistor are configured to be coupled with a common reference voltage; and wherein the source terminals of the second and fourth transistor are coupled and configured to discharge the voltage sink signal using or to the lower of the of the drain voltages of the first drain terminal and of the drain voltage of the second drain terminal.
Embodiment 15: The driver circuit according to any of the embodiments 1 to 14, wherein the bidirectional switch is a bidirectional GaN transistor.
Embodiment 16: A Method for driving a bidirectional switch, wherein the bidirectional switch comprises a gate terminal, a first and second drain terminal and a hidden, e.g., buried, common source (e.g., so that no terminal for measuring a voltage of the common source is available, e.g., a source which is not exposed), wherein the method comprises using a lower of a drain voltage of the first drain terminal and of a drain voltage of the second drain terminal, and to provide a drive signal to the gate terminal of the bidirectional switch.

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus. Some or all of the method steps may be executed by (or using) a hardware apparatus, like for example, a microprocessor, a programmable computer or an electronic circuit. In some embodiments, one or more of the most important method steps may be executed by such an apparatus.

The above-described embodiments are merely illustrative for the principles of embodiments. It is understood that modifications and variations of the arrangements and the details described herein will be apparent to others skilled in the art. It is the intent, therefore, to be limited only by the scope of the impending patent claims and not by the specific details presented by way of description and explanation of the embodiments herein.

### ASPECTS

The following provides an overview of some Aspects of the present disclosure:
Aspect 1: A driver circuit for a bidirectional switch, wherein the bidirectional switch comprises a gate terminal, a first drain terminal, a second drain terminal, and a hidden common source, wherein the driver circuit is configured to use a lower drain voltage of a drain voltage of the first drain terminal and a drain voltage of the second drain terminal in order to provide a drive signal to the gate terminal of the bidirectional switch.
Aspect 2: The driver circuit according to Aspect 1, wherein the driver circuit is configured to provide the drive signal to the gate terminal using the lower drain voltage and an overdrive voltage to turn on the bidirectional switch.
Aspect 3: The driver circuit according to Aspect 2, wherein, in a referenced operating mode, the driver circuit is configured to: provide the drive signal to the gate terminal using the lower drain voltage and the overdrive voltage to turn on the bidirectional switch; and provide a ground signal or a fixed voltage signal as the drive signal to the gate terminal in order to turn off the bidirectional switch.
Aspect 4: The driver circuit according to Aspects 2, wherein, in a floating operating mode, the driver circuit is configured to: provide the drive signal to the gate terminal using the lower drain voltage and the overdrive voltage to turn on the bidirectional switch; and provide the drive signal to the gate terminal using the lower drain voltage to turn off the bidirectional switch.
Aspect 5: The driver circuit according to Aspect 1, wherein the driver circuit comprises a voltage source circuit comprising cross-coupled transistors, wherein the voltage source circuit is configured to obtain a voltage source signal using the lower drain voltage, and wherein the driver circuit is configured to provide the drive signal to turn on the bidirectional switch using the voltage source signal.
Aspect 6: The driver circuit according to Aspect 5, wherein the voltage source circuit comprises cross-coupled NMOS transistors.
Aspect 7: The driver circuit according to Aspect 5, wherein a drain terminal of a first transistor of the cross-coupled transistors is configured to be provided with the drain voltage of the first drain terminal of the bidirectional switch, wherein a gate terminal of the first transistor is configured to be provided with the drain voltage of the second drain terminal of the bidirectional switch; wherein a drain terminal of a second transistor of the cross-coupled transistors is configured to be provided with the drain voltage of the second drain terminal of the bidirectional switch, wherein a gate terminal of the second transistor is configured to be provided with the drain voltage of the first drain terminal of the bidirectional switch, wherein the voltage source circuit comprises an output terminal to provide the voltage source signal using the lower drain voltage, and wherein the output terminal of the voltage source circuit is coupled with a source terminal of the first transistor and a source terminal of the second transistor.
Aspect 8: The driver circuit according to Aspect 7, wherein the voltage source circuit comprises voltage protection elements at the gate terminal of the first transistor and the gate terminal of the second transistor.
Aspect 9: The driver circuit according to Aspect 8, wherein the voltage protection elements comprise Zener diodes and/or NMOS transistors in diode configuration, in a stack configuration, or in a cascode configuration.
Aspect 10: The driver circuit according to Aspect 5, wherein the driver circuit comprises a charge pump, wherein the voltage source circuit is configured to provide the voltage source signal, or a scaled and/or offset version of the voltage source signal, to the charge pump, and wherein the charge pump is configured to offset the voltage source signal, in order to provide the drive signal to the gate terminal of the bidirectional switch to turn on the bidirectional switch.
Aspect 11: The driver circuit according to Aspect 10, wherein the charge pump is configured to offset the voltage source signal by an overdrive voltage.
Aspect 12: The driver circuit according to Aspect 10, wherein the charge pump is configured to offset the voltage source signal in order to compensate internal diode voltage drops of the driver circuit.
Aspect 13: The driver circuit according to Aspect 1, wherein the driver circuit comprises a voltage sink circuit with a first discharge path and a second discharge path, and wherein the voltage sink circuit is configured to discharge a voltage sink signal via the first discharge path using the drain voltage of the first drain terminal, if the drain voltage of the first drain terminal is lower than the drain voltage of the second drain terminal, in order to provide the drive signal to turn off the bidirectional switch, or wherein the voltage sink circuit is configured to discharge the voltage sink signal via the second discharge path using the drain voltage of the second drain terminal, if the drain voltage of the second drain terminal is lower than the drain voltage of the first drain terminal, in order to provide the drive signal to turn off the bidirectional switch.
Aspect 14: The driver circuit according to Aspect 13, wherein the first discharge path comprises a first transistor and a second transistor, and the second discharge path comprise a third transistor and a fourth transistor, wherein the first transistor and the third transistor are of a first channel type and wherein the second transistor and the fourth transistor are of a second channel type, which is different from the first channel type, wherein a gate terminal of the first transistor is configured to be provided with the drain voltage of the first drain terminal of the bidirectional switch, wherein a source terminal of the first transistor is coupled with a gate terminal of the second transistor, wherein a gate terminal of the third transistor is configured to be provided with the drain voltage of the second drain terminal of the bidirectional switch, wherein a source terminal of the third transistor is coupled with a gate terminal of the fourth transistor, wherein a drain terminal of the first transistor and a drain terminal of the third transistor are configured to be provided with a common drain supply voltage, wherein a drain terminal of the second transistor and a drain terminal of the fourth transistor are configured to be coupled with a common reference voltage, and wherein a source terminal of the second transistor and a source terminal of the fourth transistor are coupled and configured to discharge the voltage sink signal using the lower drain voltage.
Aspect 15: The driver circuit according to Aspect 1, wherein the bidirectional switch is a bidirectional GaN transistor.
Aspect 16: A method for driving a bidirectional switch, wherein the bidirectional switch comprises a gate terminal, a first drain terminal, a second drain terminal, and a hidden common source, the method comprising: using a lower drain voltage of a drain voltage of the first drain terminal and a drain voltage of the second drain terminal to provide a drive signal to the gate terminal of the bidirectional switch.
Aspect 17: A system configured to perform one or more operations recited in one or more of Aspects 1-16.
Aspect 18: An apparatus comprising means for performing one or more operations recited in one or more of Aspects 1-16.
Aspect 19: A non-transitory computer-readable medium storing a set of instructions, the set of instructions comprising one or more instructions that, when executed by a device, cause the device to perform one or more operations recited in one or more of Aspects 1-16.
Aspect 20: A computer program product comprising instructions or code for executing one or more operations recited in one or more of Aspects 1-16.

1. A driver circuit for a bidirectional switch, wherein the bidirectional switch comprises a gate terminal, a first drain terminal, a second drain terminal, and a hidden common source,
wherein the driver circuit is configured to use a lower drain voltage of a drain voltage—of the first drain terminal and a drain voltage of the second drain terminal in order to provide a drive signal to the gate terminal of the bidirectional switch.

2. The driver circuit according to claim 1, wherein the driver circuit is configured to provide the drive signal to the gate terminal—using the lower drain voltage and an overdrive voltage to turn on the bidirectional switch.

3. The driver circuit according to claim 2, wherein, in a referenced operating mode, the driver circuit is configured to:
provide the drive signal to the gate terminal using the lower drain voltage and the overdrive voltage to turn on the bidirectional switch; and
provide a ground signal or a fixed voltage signal as the drive signal to the gate terminal in order to turn off the bidirectional switch.

4. The driver circuit according to claims 2, wherein, in a floating operating mode, the driver circuit is configured to:
provide the drive signal to the gate terminal using the lower drain voltage and the overdrive voltage to turn on the bidirectional switch; and
provide the drive signal to the gate terminal using the lower drain voltage to turn off the bidirectional switch.

5. The driver circuit according to claim 1, wherein the driver circuit comprises a voltage source circuit comprising cross-coupled transistors,
wherein the voltage source circuit is configured to obtain a voltage source signal using the lower drain voltage, and
wherein the driver circuit is configured to provide the drive signal to turn on the bidirectional switch using the voltage source signal.

6. The driver circuit according to claim 5, wherein the voltage source circuit comprises cross-coupled NMOS transistors.

7. The driver circuit according to claim 5, wherein a drain terminal of a first transistor of the cross-coupled transistors is configured to be provided with the drain voltage of the first drain terminal—of the bidirectional switch,
wherein a gate terminal of the first transistor is configured to be provided with the drain voltage of the second drain terminal of the bidirectional switch;
wherein a drain terminal of a second transistor of the cross-coupled transistors is configured to be provided with the drain voltage of the second drain terminal of the bidirectional switch,
wherein a gate terminal of the second transistor is configured to be provided with the drain voltage of the first drain terminal of the bidirectional switch,
wherein the voltage source circuit comprises an output terminal to provide the voltage source signal using the lower drain voltage, and
wherein the output terminal of the voltage source circuit is coupled with a source terminal of the first transistor and a source terminal of the second transistor.

8. The driver circuit according to claim 7, wherein the voltage source circuit comprises voltage protection elements at the gate terminal of the first transistor and the gate terminal of the second transistor.

9. The driver circuit according to claim 8, wherein the voltage protection elements comprise Zener diodes and/or NMOS transistors in diode configuration, in a stack configuration, or in a cascode configuration.

10. The driver circuit according to claim 5, wherein the driver circuit comprises a charge pump,
wherein the voltage source circuit is configured to provide the voltage source signal, or a scaled and/or offset version of the voltage source signal, to the charge pump, and
wherein the charge pump is configured to offset the voltage source signal, in order to provide the drive signal to the gate terminal of the bidirectional switch to turn on the bidirectional switch.

11. The driver circuit according to claim 10, wherein the charge pump is configured to offset the voltage source signal by an overdrive voltage.

12. The driver circuit according to claim 10, wherein the charge pump is configured to offset the voltage source signal in order to compensate internal diode voltage drops of the driver circuit.

13. The driver circuit according to claim 1, wherein the driver circuit comprises a voltage sink circuit with a first discharge path and a second discharge path, and
wherein the voltage sink circuit is configured to discharge a voltage sink signal via the first discharge path using the drain voltage of the first drain terminal, if the drain voltage of the first drain terminal is lower than the drain voltage of the second drain terminal, in order to provide the drive signal to turn off the bidirectional switch, or
wherein the voltage sink circuit is configured to discharge the voltage sink signal via the second discharge path using the drain voltage of the second drain terminal, if the drain voltage—of the second drain terminal is lower than the drain voltage of the first drain terminal, in order to provide the drive signal to turn off the bidirectional switch.

14. The driver circuit according to claim 13, wherein the first discharge path comprises a first transistor and a second transistor, and the second discharge path comprise a third transistor and a fourth transistor,
wherein the first transistor and the third transistor are of a first channel type and wherein the second transistor and the fourth transistor are of a second channel type, which is different from the first channel type,
wherein a gate terminal of the first transistor is configured to be provided with the drain voltage of the first drain terminal of the bidirectional switch,
wherein a source terminal of the first transistor is coupled with a gate terminal of the second transistor,
wherein a gate terminal of the third transistor is configured to be provided with the drain voltage of the second drain terminal of the bidirectional switch,
wherein a source terminal of the third transistor is coupled with a gate terminal of the fourth transistor,
wherein a drain terminal of the first transistor and a drain terminal of the third transistor are configured to be provided with a common drain supply voltage,
wherein a drain terminal of the second transistor and a drain terminal of the fourth transistor are configured to be coupled with a common reference voltage, and
wherein a source terminal of the second transistor and a source terminal of the fourth transistor are coupled and configured to discharge the voltage sink signal using the lower drain voltage.

15. The driver circuit according to claim 1, wherein the bidirectional switch is a bidirectional GaN transistor.

16. A method for driving a bidirectional switch, wherein the bidirectional switch comprises a gate terminal, a first drain terminal, a second drain terminal, and a hidden common source, the method comprising:
using a lower drain voltage of a drain voltage of the first drain terminal and a drain voltage of the second drain terminal to provide a drive signal to the gate terminal of the bidirectional switch.
